(19) United States
(12) Patent Application Publication
(10) Pub. No.: US 2010/0038107 A1
(43) Pub. Date: Feb. 18, 2010

(54) SHELL FOR PORTABLE ELECTRONIC DEVICE

(75) Inventors: CHENG-WEN SU, Shindian (TW); GANG HUANG, Shenzhen City (CN); ZHONG-DAN DENG, Shenzhen City (CN); FEI LIU, Shenzhen City (CN); MIN XIE, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/507,912

(22) Filed: Jul. 23, 2009

(30) Foreign Application Priority Data
Aug. 15, 2008 (TW) 97131304

(51) Int. Cl. H05K 5/02

(52) U.S. Cl. 174/50

(57) ABSTRACT

A shell for a portable electronic device includes a transparent base shell, a light-transmittable layer, a opaque layer, and a pattern layer. The transparent base shell includes an exterior surface and an interior surface opposite to the exterior surface. The light-transmittable layer is directly formed on the interior surface and only allows a portion of light to pass there through. The opaque layer is directly formed on the light-transmittable layer. The light-transmittable layer is located between the base shell and the intermediate layer. The pattern layer covers over and around the intermediate layer to form a pattern section inside the intermediate layer. The pattern section and the pattern layer are light-transmittable by a predetermined color.

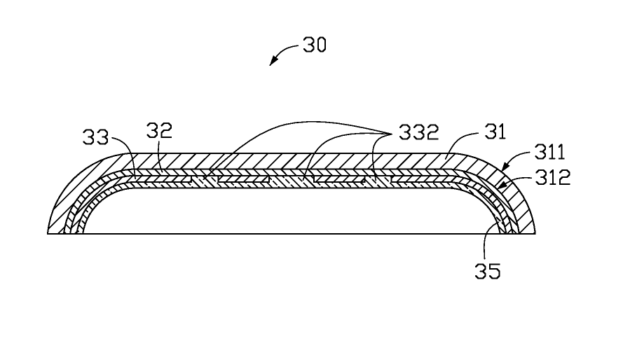

### BACKGROUND

1. Technical Field

The present disclosure relates to a shell for portable electronic devices.

2. Description of Related Art

Shells for portable electronic devices are often decorated with patterns to enhance aesthetic appearance. Typically, the patterns are directly printed/coated onto the exterior surface of the shells. However, once printed/coated, the patterns cannot be changed/altered, compromising a possible desire for variety.

Therefore, there is room for improvement within the art.

### BRIEF DESCRIPTION OF THE DRAWING

Many aspects of the disclosed shell for portable electronic devices can be better understood with reference to the drawing. The components in the drawing are not necessarily drawn to scale, the emphasis instead being placed upon clearly illustrating the principles of the disclosed shell for portable electronic devices.

The drawing is a cross section of a shell according to an exemplary embodiment.

### DETAILED DESCRIPTION

Referring to the drawing, the exemplary shell 30 for portable electronic devices (e.g., mobile phones) includes a transparent base shell 31, a light-transmittable layer 32, an opaque layer 33, and a pattern layer 35.

The base shell 31 can be Poly Carbonate (PC) or Polymethyl Methacrylate (PMMA). The base shell 31 includes an exterior surface 311 and an interior surface 312.

The light-transmittable layer 32 is directly formed on the interior surface 312 of the base shell 31. The light-transmittable layer 32 only allows a portion of light to pass there through and can be an ink layer, coating layer or vacuum deposited layer.

The intermediate layer 33 is directly formed on the light-transmittable layer 32, such that the light-transmittable layer 32 is arranged between the intermediate layer 33 and the base shell 31. The pattern layer 35 covers over and around the intermediate layer 33 to form a pattern section 332 inside the intermediate layer 33. The pattern layer 35 and the pattern section 332 are a light-transmittable ink of a predetermined color.

The portable electronic device assembled with the shell 30 further includes a plurality of light sources (not shown) below the pattern section 332 and the pattern layer 35 of the shell 30. When the light sources are not lit, the pattern section 332 is not visible, being hidden by the light transmittable layer 32. At this time, the shell 30 appears as the color of the light-transmittable layer 32. When the lighting sources is lit, light therefrom penetrates the pattern layer 35, the pattern section 332 and the light-transmittable layer 32 in order to the exterior. At this stage, the shell 30 appears as the color of the pattern section 332 and the color of the light-transmittable layer 32. Light-transmittable layer 32, combined with the pattern section 332 below the transparent base shell 31 is thus visible. Accordingly, the portable electronic device presents a first appearance when the internal light sources are unlit and a second appearance when the internal light sources are lit.

It is to be understood, however, that even through numerous characteristics and advantages of the exemplary embodiment have been set forth in the foregoing description, together with details of the structure and function of the embodiment, the disclosure is illustrative only, and changes may be made in detail, especially in matters of shape, size, and arrangement of parts within the principles of the embodiment to the full extent indicated by the broad general meaning of the terms in which the appended claims are expressed.

What is claimed is:

1. A shell for a portable electronic device, comprising:
a transparent base shell comprising an exterior surface and an interior surface opposite to the exterior surface;
a light-transmittable layer directly formed on the interior surface, the light-transmittable layer only allowing a portion of light to pass there through;
an opaque layer directly formed on the light-transmittable layer, the light-transmittable layer located between the base shell and the intermediate layer; and
a pattern layer covering over and around the intermediate layer to form a pattern section inside the intermediate layer, wherein the pattern section and the pattern layer are light-transmittable by a predetermined color.

2. The shell as claimed in claim 1, wherein the light-transmittable layer is ink, coating, or vacuum deposited layer.

3. The shell as claimed in claim 1, wherein the pattern section and the pattern layer comprise light-transmittable ink of a predetermined color.

4. The shell as claimed in claim 3, wherein the pattern layer and the pattern section comprise colored ink.

5. A shell for a portable electronic device, comprising:
a transparent base shell;
a opaque layer;
a pattern section located inside the opaque layer; and
a light-transmittable layer only allowing a portion of light to pass there through and configured for concealing the pattern section from view when the pattern section is not lit.

6. The shell as claimed in claim 5, further comprising a pattern layer, wherein:
the light-transmittable layer is directly formed on the base shell;
the intermediate layer is directly formed on the light-transmittable layer; and
the pattern layer including the pattern section is directly formed on the intermediate layer, the light-transmittable layer located between the base shell and the intermediate layer, and the intermediate layer located between the pattern layer and the light-transmittable layer.

7. The shell as claimed in claim 6, wherein the light-transmittable layer is ink, coating, or vacuum deposited layer.

8. The shell as claimed in claim 6, wherein the pattern section and the pattern layer comprise light-transmittable ink of a predetermined color.

9. The shell as claimed in claim 8, wherein the pattern layer and the pattern section comprise colored ink.
